(19) United States
(12) Patent Application Publication
(10) Pub. No.: US 2017/0148949 A1
(43) Pub. Date: May 25, 2017

(54) Nitride Light Emitting Diode Structure

(71) Applicant: XIAMEN SANAN OPTOELECTRONICS TECHNOLOGY CO., LTD., Xiamen (CN)

(72) Inventors: Yung-ling LAN, Xiamen (CN); Chia-hung CHANG, Xiamen (CN); Chan-chan LING, Xiamen (CN); Hsiang-lin HSIEH, Xiamen (CN); Hsiang-pin HSIEH, Xiamen (CN); Zhibo XU, Xiamen (CN)

(73) Assignee: XIAMEN SANAN OPTOELECTRONICS TECHNOLOGY CO., LTD., Xiamen (CN)

(21) Appl. No.: 15/426,490

(22) Filed: Feb. 7, 2017

Related U.S. Application Data
(63) Continuation of application No. PCT/CN2015/097358, filed on Dec. 15, 2015.

(30) Foreign Application Priority Data
Feb. 6, 2015 (CN) 201510062588.8

(51) Int. Cl. H01L 33/06; H01L 33/32; H01L 33/12; H01L 33/14

(52) U.S. Cl. CPC H01L 33/06; H01L 33/14; H01L 33/32; H01L 33/12

(57) ABSTRACT

A nitride light-emitting diode (LED) structure includes a substrate, a buffer layer, an N-type layer, a stress release layer, a quantum well light-emitting layer and a P-type layer, wherein, between the N-type layer and the stress release layer, an electric field distribution layer is inserted, which is an n-doped multi-layer GaN structure with growth temperature equaling to or lower than that of the quantum well light-emitting layer; and GaN layers of different doping concentrations are applied to gradually reduce electric field concentration and make uniform spreading of current, thus enhancing electrostatic voltage endurance, reducing failure rate during usage, improving operational reliability and extending service life of the nitride semiconductor component.

### CROSS-REFERENCE TO RELATED APPLICATIONS

The present application is a continuation of, and claims priority to, PCT/CN2015/097358 filed on Dec. 15, 2015, which claims priority to Chinese Patent Application No. 201510062588.8 filed on Feb. 6, 2015. The disclosures of these applications are hereby incorporated by reference in their entirety.

### BACKGROUND

In recent years, with focus on luminance improvement, light emitting diode

(LED) components are expected to be employed in the lighting field for energy saving and carbon reduction. In conventional GaN-based LED, a sapphire (Al₂O₃) substrate is commonly used and a GaN epitaxial structure is formed on the surface. However, because of lattice constant mismatch and the difference in coefficient of thermal expansion between GaN and the sapphire substrate, large amount of defects exist in GaN-based LED, which may even spread to the entire epitaxial layer through the quantum well light emitting layer. These defects have great influence on leakage and ESD electric characteristics of the GaN-based LED. Therefore, heat generated when discharge current flows through the PN junction of the LED is likely to cause melting of local media between two electrodes of the PN junction, leading to short circuit or leakage of the PN junction.

With expanding application of nitride semiconductor components, besides high luminance, it becomes increasingly important to decrease component operation voltage and improve electrostatic voltage endurance.

### SUMMARY

To improve electrostatic voltage endurance of the prior art, embodiments disclosed herein provide a nitride semiconductor component with an electric field distribution layer so that electric field concentration is reduced and current is spread uniformly, thus enhancing electrostatic voltage endurance and component characteristics.

To achieve the aims mentioned above, various embodiments disclosed herein provide a nitride light emitting diode structure, comprising: a substrate, a buffer layer, an N-type layer, a stress release layer, a quantum well light-emitting layer and a P -type layer, wherein, between the N-type layer and the stress release layer, an electric field distribution layer is inserted, which is an n-doped multi-layer GaN structure with growth temperature equaling to or lower than that of the quantum well light-emitting layer.

Preferably, the number of electric field distribution layers is n, where n≧3.

Preferably, the electric field distribution layer at least comprises a GaN layer

A with doping concentration of 5×10¹⁸-1×10¹⁹/cm³.

Preferably, the electric field distribution layer at least comprises a GaN layer B with doping concentration of 1×10¹⁸-5×10¹⁸/cm³.

Preferably, the electric field distribution layer at least comprises a GaN layer

C with doping concentration of 1×10¹⁷-1×10¹⁸/cm³.

Preferably, among electric field distribution layers, impurity concentration of at least one layer is higher than that of the stress release layer.

Preferably, the electric field distribution layer is 50-800 Å thick.

Preferably, growth temperature of the electric field distribution layer is 700° C.-900° C.

In another aspect, a light-emitting system is provided including a plurality of the LEDs described above. The light-emitting system can be used, for example, for lighting, display, signage, etc.

Various embodiments of the present disclosure can have one or more of the advantageous effects as follows: in the electric field distribution layer of the nitride semiconductor component according to some embodiments, GaN layers of different doping concentrations are applied to gradually reduce electric field concentration and make uniform spreading of current, thus enhancing electrostatic voltage endurance, reducing failure rate during usage, improving operational reliability and extending service life of the nitride semiconductor component.

### BRIEF DESCRIPTION OF THE DRAWINGS

The accompanying drawings, which are included to provide a further understanding of the disclosure and constitute a part of this specification, together with the embodiments, are therefore to be considered in all respects as illustrative and not restrictive. In addition, the drawings are merely illustrative, which are not drawn to scale.

FIG. 1 is a side view of a nitride light emitting diode structure according to Embodiment 1 of the present disclosure.

FIG. 2 is partial structural diagrams of a nitride light emitting diode structure according to some embodiments.

FIG. 3 illustrates a first variation of the LED structure illustrated in FIG. 2.

FIG. 4 illustrates a second variation of the LED structure illustrated in FIG. 2.

FIG. 5 illustrates a third variation of the LED structure illustrated in FIG. 2.

FIG. 6 illustrates a fourth variation of the LED structure illustrated in FIG. 2.

FIG. 7 illustrates a fifth variation of the LED structure illustrated in FIG. 2.

In the drawings: 1: substrate; 2: buffer layer; 3: N-type layer; 4: electric field distribution layer; 401: GaN layer A; 402: GaN layer B; 403: GaN layer C; 5: stress release layer; 6: quantum well light-emitting layer; 7: P-type layer.

### DETAILED DESCRIPTION

The embodiments of the present disclosure will be described in detail with reference to the accompanying drawings and embodiments.

### Embodiment 1

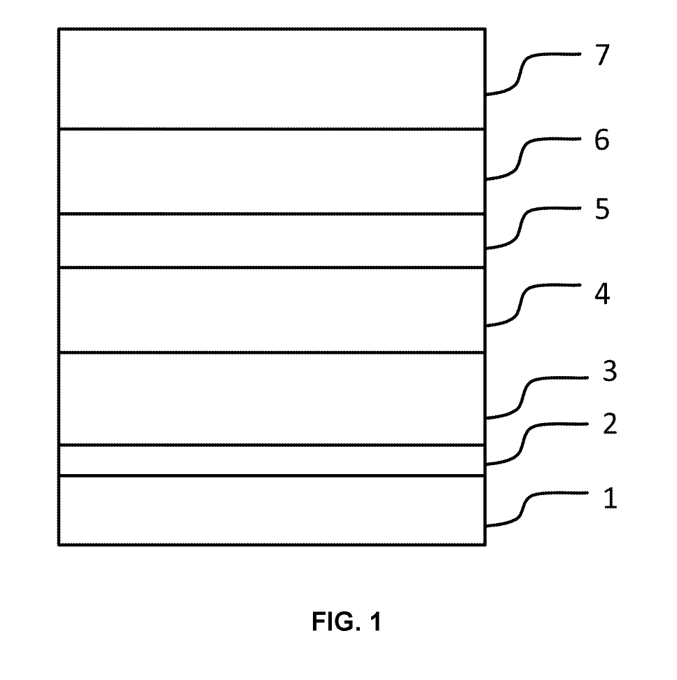

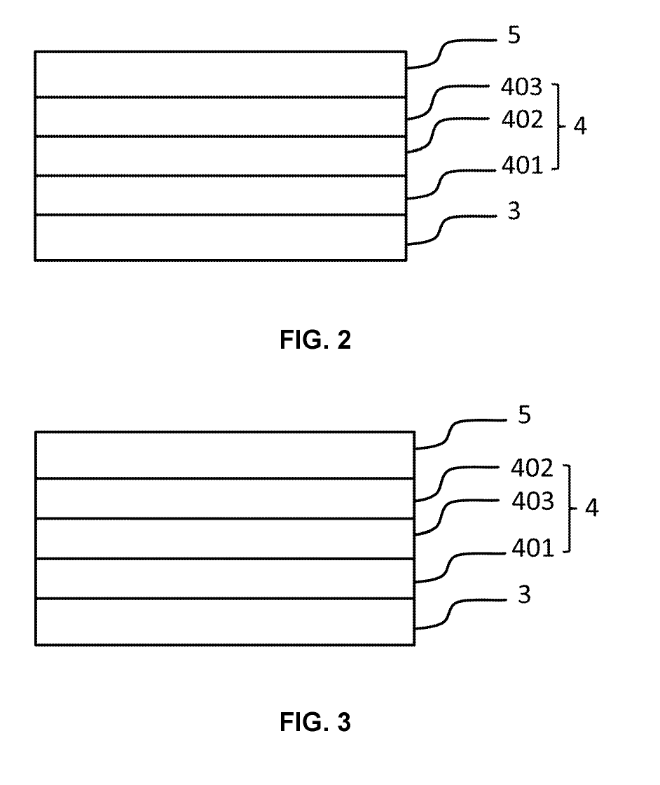

Referring to FIGS. 1 and 2, some embodiments disclosed herein provide a nitride light emitting diode structure, comprising: a substrate 1, on which a buffer layer 2, an N-type layer 3, an electronic field distribution layer 4, a stress release layer 5, a quantum well light emitting layer 6 and a P-type layer 7 are formed in sequence, wherein, the substrate 1 is made of any one of Al₂O₃ monocrystal (sapphire), SiC (6H—SiC or 4H—SiC), Si, GaAs, GaN or a single crystalline oxide with lattice constant approximate to that of the nitride semiconductor layer; the buffer layer 2 is composed of Al_{1-x-y}In_{y}GaₓN, where O≦X<1, and O<Y<1; the N-type layer 3 is composed of Si-doped GaN, with growth temperature of 900° C.-1,100° C. and Si doping concentration higher than that of the electronic field distribution layer 4; the electronic field distribution layer 4 is an n-type GaN-doped structure having at least 3 layers (number of layers: n), in which, impurity concentration of at least one layer is higher than that of the stress release layer 5. In this embodiment, Si doping is preferred with thickness of 50 Å-800 Å, and growth temperature is 700° C.-900° C., equaling to or higher than that of the quantum well light emitting layer 6; the stress release layer 5 is an InGaN or InGaN/GaN super-lattice structure with doping concentration of 5×10¹⁷-1×10¹⁸/cm³, and growth temperature of 800° C.-900° C.; the quantum well light emitting layer 6 is alternatively formed by a Si-doped quantum barrier (n-GaN) layer and an In-doped quantum well (InGaN) layer under growth temperature of 800° C.-880° C. and with periods of 1-50; and the P -type layer 7 is 100-4,000 Å thick with compositions of Mg-doped GaN under growth temperature of 800° C.-1,000° C.

In this embodiment, the electronic field distribution layer 4 at least comprises a GaN layer A 401 with doping concentration of 5×10¹⁸-1×10¹⁹/cm³, a GaN layer B 402 with doping concentration of 1×10¹⁸-5×10¹⁸/cm³ and a GaN layer C 403 with doping concentration of 1×10¹⁷-1×10¹⁸/cm³, and these three GaN layers 401, 402 and 403 are stacked on the N-type layer 3 in descending order of doping concentration; as the electronic field distribution layer 4 comprises GaN layers in variety of doping concentrations, when a light emitting diode having this structure is applied with electronic field, the GaN layers with various doping concentrations can effectively scatter and buffer the electronic field to enhance electrostatic voltage endurance.

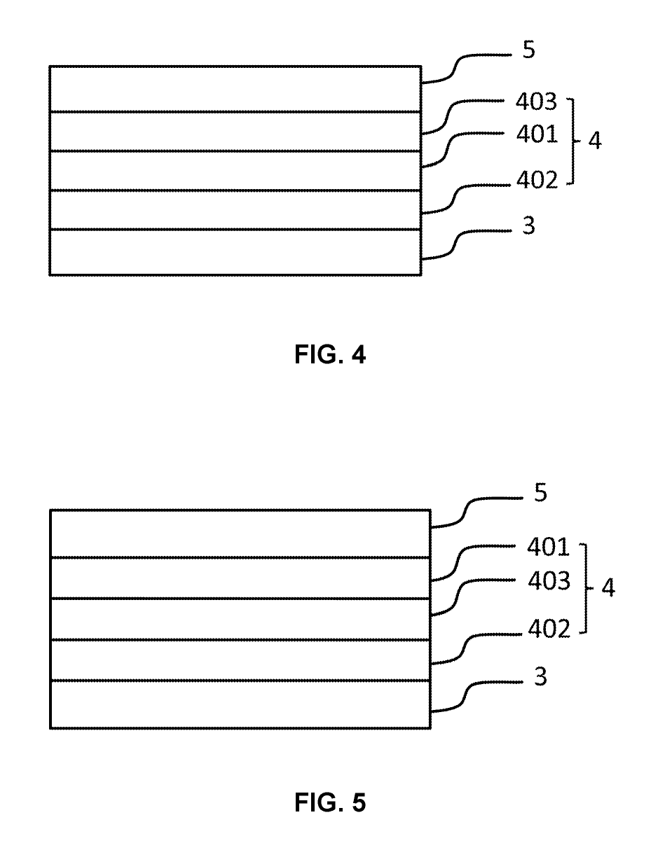

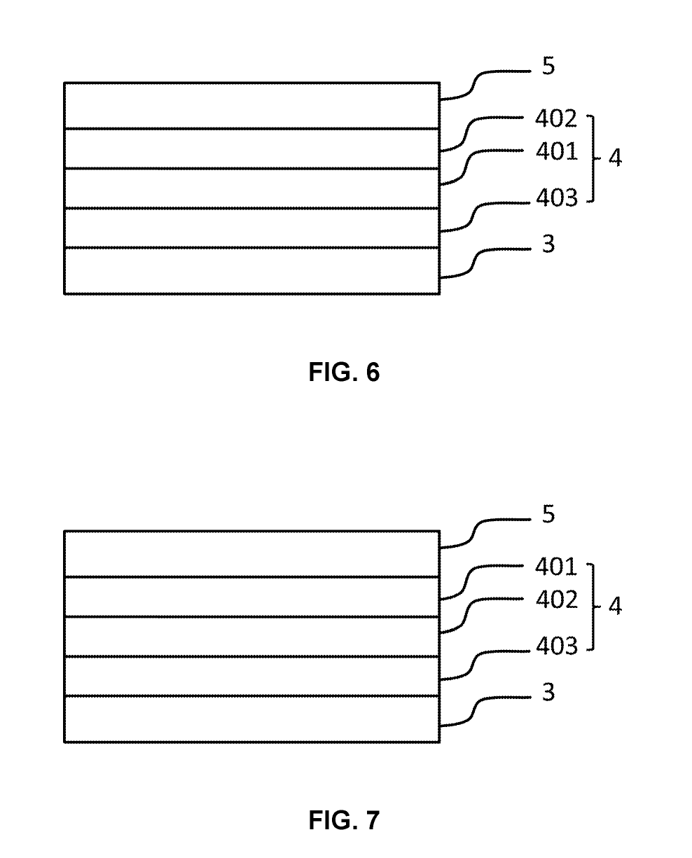

In addition, referring to FIGS. 3-7, variations of this embodiment is provided, wherein stacking sequence of three GaN layers 401, 402 and 403 of different doping concentrations on the N-type layer 3 can be adjusted flexible according to production requirements so that the electronic field is scattered and the LED component characteristics are enhanced. For example, FIG. 2 is partial structural diagrams of a nitride light emitting diode structure according to some embodiments, FIG. 3 illustrates a first variation of the LED structure illustrated in FIG. 2, FIG. 4 illustrates a second variation of the LED structure illustrated in FIG. 2, FIG. 5 illustrates a third variation of the LED structure illustrated in FIG. 2, FIG. 6 illustrates a fourth variation of the LED structure illustrated in FIG. 2, and FIG. 7 illustrates a fifth variation of the LED structure illustrated in FIG. 2.

All references referred to in the present disclosure are incorporated by reference in their entirety. Although specific embodiments have been described above in detail, the description is merely for purposes of illustration. It should be appreciated, therefore, that many aspects described above are not intended as required or essential elements unless explicitly stated otherwise. Various modifications of, and equivalent acts corresponding to, the disclosed aspects of the exemplary embodiments, in addition to those described above, can b e made by a person of ordinary skill in the art, having the benefit of the present disclosure, without departing from the spirit and scope of the disclosure defined in the following claims, the scope of which is to be accorded the broadest interpretation so as to encompass such modifications and equivalent structures.

1. A nitride light-emitting diode (LED), comprising:
a substrate;
a buffer layer;
an N-type layer;
a stress release layer;
a quantum well light-emitting layer; and
a P -type layer;
wherein:
between the N-type layer and the stress release layer, an electric field distribution layer is inserted; and
the electric field distribution layer comprises a multi-layer GaN structure grown with a growth temperature equal to or lower than a growth temperature of the quantum well light-emitting layer.

2. The nitride LED of claim 1, wherein the electric field distribution layer has a number of n layers, where n>3.

3. The nitride LED of claim 1, wherein the electric field distribution layer is an n-type doped layer.

4. The nitride LED of claim 1, wherein the electric field distribution layer comprises a first GaN layer A with a doping concentration of 5×10¹⁸-1×10¹⁹/cm³.

5. The nitride LED of claim 1, wherein the electric field distribution layer comprises a second GaN layer B with a doping concentration of 1×10¹⁸-5×10¹⁸/cm³.

6. The nitride LED of claim 1, wherein the electric field distribution layer comprises a third GaN layer with a doping concentration of 1×10¹⁷-1×10¹⁸/cm³.

7. The nitride LED of claim 1, wherein the electric field distribution layer comprises at least one layer with an impurity concentration higher than an impurity concentration of the stress release layer.

8. The nitride LED of claim 1, wherein the electric field distribution layer is 50-800 Å thick.

9. The nitride LED of claim 1, wherein the growth temperature of the electric field distribution layer is 700° C.-900° C.

10. The nitride LED of claim 1, wherein the stress release layer is an InGaN or an InGaN/GaN super lattice structure.

11. A light-emitting system comprising a plurality of nitride light-emitting diodes (LEDs), each LED comprising:
a substrate;
a buffer layer;
an N-type layer;
a stress release layer;
a quantum well light-emitting layer; and
a P -type layer;
wherein:
between the N-type layer and the stress release layer, an electric field distribution layer is inserted; and
the electric field distribution layer comprises a multi-layer GaN structure grown with a growth temperature equal to or lower than a growth temperature of the quantum well light-emitting layer.

12. The system of claim 11, wherein the electric field distribution layer has a number of n layers, where n>3.

13. The system of claim 11, wherein the electric field distribution layer is an n-type doped layer.

14. The system of claim 11, wherein the electric field distribution layer comprises a first GaN layer A with a doping concentration of 5×10¹⁸-1×10¹⁹/cm³.

15. The system of claim 11, wherein the electric field distribution layer comprises a second GaN layer B with a doping concentration of 1×10¹⁸-5×10¹⁸/cm³.

16. The system of claim 11, wherein the electric field distribution layer comprises a third GaN layer with a doping concentration of 1×10¹⁷-1×10¹⁸/cm³.

17. The system of claim 11, wherein the electric field distribution layer comprises at least one layer with an impurity concentration higher than an impurity concentration of the stress release layer.

18. The system of claim 11, wherein the electric field distribution layer is 50-800 Å thick.

19. The system of claim 11, wherein the growth temperature of the electric field distribution layer is 700° C.-900° C.

20. The system of claim 11, wherein the stress release layer is an InGaN or an InGaN/GaN super lattice structure.
